(19) United States
(12) Patent Application Publication
(10) Pub. No.: US 2010/0128901 A1
(43) Pub. Date: May 27, 2010

(54) WIND NOISE REJECTION APPARATUS

(76) Inventor: David Herman, Brighton (GB)

Correspondence Address: RENNER KENNER GREIVE BOBAK TAYLOR & WEBER, FIRST NATIONAL TOWER FOURTH FLOOR, 106 S. MAIN STREET, AKRON, OH, 44308, US

(21) Appl. No.: 12/527,197

(22) PCT Filed: Feb. 18, 2008
(86) PCT No.: PCT/GB08/00545

§ 371 Date: Jan. 19, 2010

(30) Foreign Application Priority Data
Mar. 9, 2007 (GB) 0704682.4
Feb. 18, 2008 (GB) 0703059.6

(51) Int. Cl. H03G 5/00; H04R 19/04

(52) U.S. Cl. 381/98; 381/359

(57) ABSTRACT

An apparatus for reduction of wind noise comprised of an electro-acoustic transducer arrangement with at least one transducer element. The exposed structure is covered with at least one thin layer of wind-resistive material, in the form of a mesh, and optionally includes one or more further layers of felt, foam and/or mesh in any combination. Where a plurality of elements is provided, the electrical outputs of the elements may be added together to provide an output signal with increased signal to wind noise ratio. The signal may be subject to additional signal processing such as filtering and/or level sensitive signal inhibition.

The present invention relates to the use of electro-acoustic transducers and more particularly to an arrangement which reduces the effects of wind noise in the case of a microphone.

The problem with wind noise in relation to microphones is well known and many solutions have been proposed. Such proposals have often required the use of complex signal processing equipment which increases the cost of the microphone and associated system quite considerably. Simpler solutions such as providing the microphone with a wind screen of some sort have also been proposed which can be effective, however, they are bulky.

The present invention provides an arrangement comprising at least one transducer element covered by a layer or layers of wind resistive material the purpose of which is to pre-attenuate the wind. The wind resistive material comprises a mesh either alone or in combination with one or more layers of a thin foam and/or felt, and may optionally include additional mesh layers. Preferably, the external surface of the wind resistive material is specially shaped and consists of a plurality of convex surfaces which are seamlessly joined. The inventor has found that the best results are achieved when the external surface is shaped to form a three dimensional hyperbolic shape. The or each transducer element is located within the volume defined by the shaped resistive material so as to be fully exposed to the wind.

The technology works with omni-directional microphones and, to a lesser degree, with bidirectional and unidirectional microphones.

In practice, a preferred arrangement uses a minimum of three microphones, although the described mesh of wind resistive material also provides an advantageous wind noise reduction effect when used with one or two microphones.

An advantage of the present invention is that there is no requirement for there to be a desired sound source present for the invention to work.

In order that the present invention be more readily understood, an embodiment thereof will now be described by way of example with reference to the accompanying drawings, in which:—

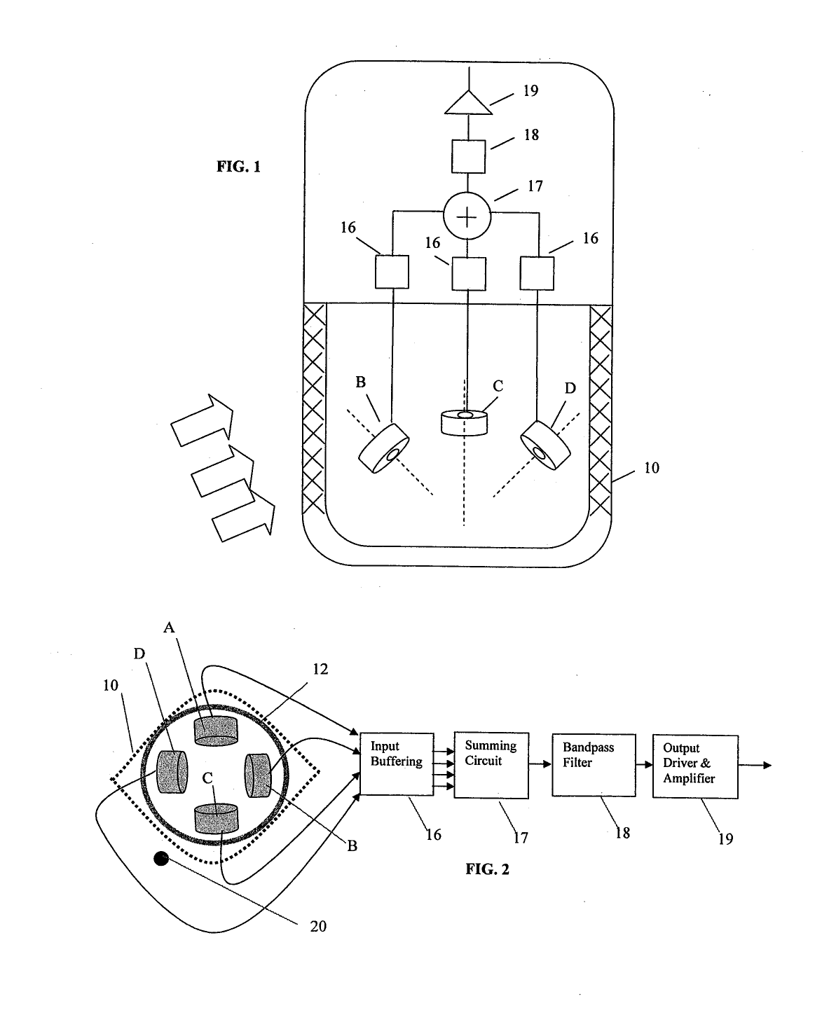

FIG. 1 shows diagrammatically a first embodiment of a microphone arrangement in accordance with the present invention;

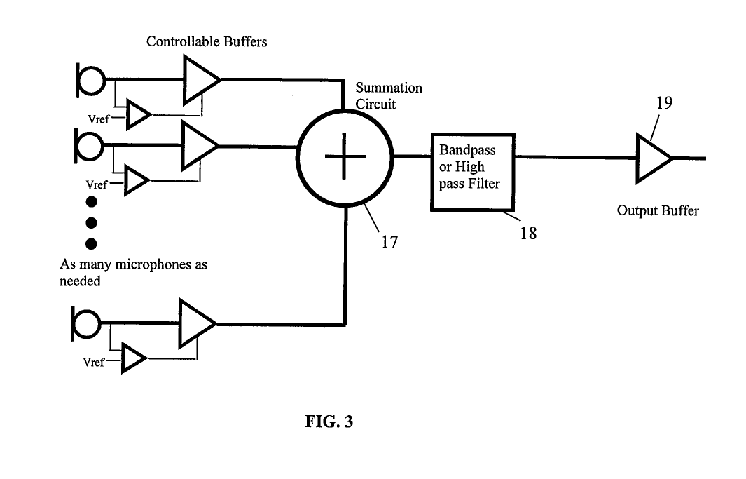

FIG. 2 shows diagrammatically a second embodiment of the present invention; and,

FIG. 3 shows a block diagram of a further arrangement including modified circuitry according to the present invention. The purpose of this enhancement is to detect the microphone(s) that are producing the most wind noise and prevent their output(s) from reaching the summation circuit.

Embodiments of the present invention comprise one or more transducer elements. Where more than one transducer element is provided, a further wind noise reduction effect may be achieved by summing the outputs of the transducer elements to produce a single output. It is preferable to utilise omni-directional transducer elements but unidirectional or bidirectional elements may also be used but with reduced performance levels. An omni-directional transducer element is one where there is a single port in a housing with the diaphragm of the transducer disposed within the housing such that it responds equally to sounds from different directions. The disposition of the elements with respect to one another is not significant as the further wind noise reduction effect achieved by summing the outputs can be obtained irrespective of the direction that the elements face with respect to the sound source, although optimal performance is achieved when the elements face in different directions. However, there may be circumstances in which the elements are positioned relative to each other such that their ports are equidistant from a desired sound source. In one such arrangement, the elements can be located on the surface of an imaginary sphere so that they are all equidistant from the desired sound source.

Furthermore, the microphones should be shielded from the wind with a thin resistive material that may surround them or at least be placed over all exposed hole(s) common to all microphone elements. This material advantageously consists of a mesh with perforation sizes about 125 microns or smaller, which may be combined with a thin felt or foam. The foam can be similar to that used to cover the ear pieces of headphones, although other arrangements are also effective. Preferably, the material should not significantly adversely affect the frequency response of the elements.

Referring now to FIG. 1, this shows an arrangement which comprises a plurality of omni-directional transducer elements covered with a layer of resistive material 10 in the form of a mesh where the holes are of the order of less than 125 microns, preferably less than around 75 microns, and more preferably 40-50 microns. The mesh may, for example, be made of wire. It should be noted that the same type of resistive material may be used in an arrangement having a single transducer element. If desired, the mesh may be combined with a layer of thin felt or acoustic foam similar to that used to cover the ear pieces of headphones. The shaped mesh and layer of felt or foam may be combined in a number of different ways, not simply with the mesh covering the felt or foam as shown in FIG. 2. For example, the felt or foam may cover the mesh or there may be alternating layers of mesh and felt or foam in any combination to achieve better wind noise rejection at the expense of adding bulk. As such, the material 10 does not affect the frequency response of the element or elements.

In the present embodiment, a plurality of transducer elements is provided, and the outputs of the elements are fed through buffer circuits 16 and added together by a summation circuit 17. After summation, the signals may be filtered by a high pass or band pass filter circuit 18 before being fed to an output buffer 19. It is to be noted that the ports of the elements should preferably face in different directions. In the case where a single transducer element is provided, the same filtering technique may be applied to the output signal of the single element, rather than to the summed outputs referred to above.

In the embodiment of FIG. 1, three omni-directional microphone elements are present and are disposed relative to each other so that they are physically orientated in three dimensions. The elements are covered with material 10 as described above. The B and D elements in FIG. 1 are physically disposed in the same plane but the ports of the elements B and D point generally at a zone containing the sound source. In other words, the ports of the two elements are in the same plane but point at different angles. The middle element C is physically above the plane containing the elements B and D but it is tilted. Thus, it is also pointing at the zone containing the sound source.

Turning now to FIG. 2, this shows a microphone arrangement where four microphones are disposed inside a wind shield formed by an outer layer of a fine mesh 10 of the type disclosed above surrounding a layer of thin felt or foam 12, although the same wind shield can be used with an arrangement having any number of microphones. The microphones A, B, C and D are orientated in three dimensions optionally facing towards a common point represented by a dot 20 which can be considered to be any point in space in or out of the plane of the paper.

As in the case of the arrangement in FIG. 1, the outputs of the microphones are buffered and then summed together in any convenient manner with equal weighting or gain using any suitable analogue or digital technique. After summation, the output may be passed through a high pass or band pass filter whose lower cut off frequency is about 200 Hz to further improve the wind noise rejection. The filtered output is fed to a driver and amplifier circuit. The filtering may also be done before the addition process if desired or, in an arrangement having only a single microphone, in the absence of any addition process.

It is to be noted that the wind rejection effect is also achieved if the microphones do not point towards the sound source; it is sufficient that they point in different directions. A further reduction in wind noise may be achieved by orientating each microphone so that its port points towards the sound source depending on the application.

The omni-directional element(s) may be located within a housing provided with or formed by a layer of wind resistant material. Alternatively, the element(s) may be located in a case with one or more holes, in which case only the holes need be covered with a layer of resistive material, although this arrangement is not ideal. Furthermore, this material may be as described above which would not therefore burden the practical manufacturability of the invention. The shape of the acoustic screen comprising a combination of mesh and felt or foam has an effect on the wind noise rejection performance with optimum performance being achieved with a plurality of convex shaped portions. Preferably, the convex shaped portions constitute a three dimensional generally hyperbolic shape. In particular, forming the screen with pinched portions between the shaped portions has been found to disrupt wind effectively.

One intended use is that the microphone elements will be mounted in some manner so that the array is in a relatively fixed position with respect to the desired sound source. In the case of a microphone for use with live speech, the microphone could be attached to the end of a boom which itself is part of an ear piece or headset. In another example, the microphone could be mounted in a helmet which may have an oxygen feed generating an internal source of unwanted wind noise, or it could be used to replace the existing microphone in existing outside broadcast arrangements where the microphone is located within a cage which is arranged to be held against the face of a user with the microphone itself spaced from the user's mouth by a defined distance. Hearing aids experience wind noise interference and can benefit from this invention. Applications include but are not limited to wired or Bluetooth PHF (Personal Hands Free) devices for use with a mobile ‘phone. The microphone may be used with a camera such that the desired sound is coming from approximately in front of the camera, or indeed it may used to capture sounds from any direction. The people speaking may be stationary or moving without affecting the desired wind noise rejection performance.

It is to be emphasised that the microphone elements described in relation to FIGS. 1 and 2 will enhance any sound whether or not the desired sound source is physically located in front of a port of one or more of the elements. Thus, precise location of the microphone with respect to, say, the mouth, is not required and it has been found that an array of microphone elements as described in relation to FIG. 1 or FIG. 2 will function satisfactorily even if the array is non-favourably orientated near a suitable sound source and consequently receiving only off-axis signals.

FIG. 3 shows a block diagram of a microphone array with electronic circuitry for carrying out signal processing if such is desired for any particular application e.g. should one or more of the elements be producing an inappropriate signal and it be desired to exclude it from the summed output. There are many other methods for achieving this using either analogue or digital solutions. Although not shown in this figure, the microphone elements are covered by a common thin layer of resistive material 10 as before. The outputs of the elements are fed to controllable buffers where the signals are compared with a reference voltage so that the signal from the worst affected element(s) is/are inhibited. Thereafter, the signals are added together and fed to an output buffer 19 after processing by a filter circuit 18 which applies high pass or band pass filtering with a lower cut-off frequency about 200 Hz. Other notch and band pass filtering can be provided to compensate for any slight loss of speech fidelity. Similar filtering techniques may also be applied to the output from a single element, in which case no summation is required.

The array of microphone elements replaces a conventional microphone and thus can be used as a direct replacement for such a microphone by being incorporated into equipment during manufacture. This may be achieved by incorporating the microphone elements and the associated signal addition circuitry as components of the larger equipment during manufacture. Alternatively, the microphone elements could be packaged with or without their associated signal addition circuitry and provided to manufacturers as a module.

The arrangement of one or more preferably omni-directional transducer elements, whether or not in modular form, may be mounted in a housing which may be waterproof or splashproof but is provided with an array of perforations covered by a layer of wind resistive material. The housing may be provided with means for attaching the array of elements to another piece of equipment on a user, e.g. by means of a spring clip. The present invention has wide application either as component parts of a larger piece of equipment or as a module for the larger equipment. To give some indication of the various applications, a number of different implementations will now be described. This is not an exhaustive list.

One implementation is to replace an outside broadcast microphone as indicated previously. Another is to replace the microphone in a mobile phone or part of a PHF kit for a mobile phone. Another is to replace the microphone in portable recording devices.

A further implementation is to replace the microphone in a camera or video camera, video camera-phone, or other portable communication devices. This could be the microphone that is pointed at the user so that the user can comment on the scene being photographed or videoed. While the above arrangements are all disclosed with reference to wind and microphones, the same principles can be applied to other fluids such as water, in which case the transducer is normally termed a hydrophone.

Further, the omni-directional transducer element(s) can be fabricated using semi-conductor techniques which allows the array of elements to occupy very little space. A MEMs microphone is sometimes referred to as a SiMIC (Silicon Microphone). Using one or more miniature omni-directional microphone elements in an appropriate array permits a version of the invention to be utilised in a hearing aid that is suitable for use in breezy or windy conditions, for example outdoors.

Although the drawings show a simple shape for the wind resistive material, tests have shown that utilising a special shape for the resistive material has advantages. As shown in FIG. 2, the one or more microphone elements are located in a relatively rigid enclosure of the fine mesh that has a number of convex shaped portions when viewed in plan.

1. An electro-acoustic transducer arrangement comprising at least one transducer element, and wind resistive material covering the transducer element, characterised in that the resistive material is in the form of a mesh having holes less than approximately 125 microns in size, and is shaped to form an enclosed volume which may be exposed to wind and which is arranged to contain the or each transducer element.

2. A transducer arrangement according to claim 1, wherein the mesh has holes of 40-50 microns.

3. A transducer arrangement according to claim 2, wherein the or each transducer element is an omni-directional element.

4. A transducer arrangement according to claim 1, wherein the wind resistive material comprises a layer of felt or foam material.

5. A transducer arrangement according to claim 1, wherein the wind resistive material is shaped to form a plurality of convex portions.

6. A transducer arrangement according to claim 1, wherein the wind resistive material is shaped to form a generally three dimensional hyperbolic shape.

7. A transducer arrangement according to claim 5, wherein the external surface of the wind resistive material is formed with pinched portions.

8. A transducer arrangement according to claim 1, wherein there are a plurality of transducer elements with each transducer facing a unique direction, and the outputs of the elements are summed.

9. A transducer arrangement according to claim 1, wherein the or each transducer element is a microphone element and is located on a boom attached to a user's head so as to be located pointing at the user's mouth.

10. A transducer arrangement according to claim 1, wherein the or each element is a microphone element and is located on a helmet so as to be pointing at a user's mouth.

11. A transducer arrangement according to claim 1 wherein there are a plurality of elements manufactured using semiconductor micro fabrication techniques.

12. A transducer arrangement according to claim 1, wherein the outputs of the or each element is subjected to filtering in order to reduce noise.

13. A transducer arrangement according to claim 12, wherein the filtering utilises a high pass or band pass filter.

14. A transducer arrangement according to claim 12, wherein the filter passes frequencies above about 200 Hz.

15. A transducer module comprising a housing within which is provided a transducer arrangement as claimed in claim 1, wherein an outer surface of the housing is semi-permeable in one direction and is splashproofed or waterproofed.

16. A module as claimed in claim 15, wherein an array of perforations is provided in said splashproofing or waterproofing housing adjacent to each microphone.

17. A module as claimed in claim 15 wherein mounting means are provided in the form of an over-moulded package.

18. A camera incorporating a transducer arrangement according to claim 1.

19. A portable communication device incorporating a transducer arrangement according to claim 1.

20. A portable communication device according to claim 19, wherein the device communicates data, as well as sound.

21. A hearing aid incorporating a transducer arrangement according to claim 1.

22. A recording device incorporating a transducer arrangement according to claim 1.
